(19) United States
(12) Patent Application Publication
(10) Pub. No.: US 2013/0180577 A1
(43) Pub. Date: Jul. 18, 2013

(54) PHOTOELECTRIC CONVERSION DEVICE

(71) Applicant: SEMICONDUCTOR ENERGY LABORATORY CO., LTD., Atsugi-shi (JP)

(72) Inventors: Yoshinobu ASAMI, Isehara (JP); Riho Kataishi, Atsugi (JP)

(73) Assignee: SEMICONDUCTOR ENERGY LABORATORY CO., LTD., Atsugi-shi (JP)

(21) Appl. No.: 13/732,604

(22) Filed: Jan. 2, 2013

(30) Foreign Application Priority Data
Jan. 18, 2012 (JP) 2012-007650
May 9, 2012 (JP) 2012-107483

(51) Int. Cl. H01L 31/0352

(52) U.S. Cl. CPC H01L 31/0352
USPC 136/255

(57) ABSTRACT

To provide a photoelectric conversion device including a passivation film in which an opening for connection to an electrode does not need to be provided. The photoelectric conversion device includes, between a pair of electrodes, a silicon substrate having p-type conductivity; a silicon semiconductor layer having n-type conductivity which is provided over one surface of the silicon substrate and in contact with one of the pair of electrodes; and an oxide semiconductor layer having p-type conductivity which is provided over the other surface of the silicon substrate and in contact with the other of the pair of electrodes. The oxide semiconductor layer is formed using an inorganic compound which contains an oxide of a metal belonging to any of Groups 4 to 8 in the periodic table as its main component and whose band gap is greater than or equal to 2 eV.

### BACKGROUND OF THE INVENTION

1. Field of the Invention

The present invention relates to a photoelectric conversion device using a silicon substrate.

2. Description of the Related Art

In recent years, photoelectric conversion devices that do not produce carbon dioxide during power generation have received attention as a measure against global warming. As typical examples thereof, solar cells have been known which use silicon substrates such as single crystalline and polycrystalline silicon substrates.

In a photoelectric conversion device using a silicon substrate, it is important to control minority carriers. Improvement in lifetime of minority carriers, that is, an increase in lifetime of a bulk of a silicon substrate and a decrease in the surface recombination velocity contribute to improvement in conversion efficiency.

In order to increase the bulk lifetime of the silicon substrate, it is effective to reduce crystal defects and reduce impurities, which are performed mainly at the time of forming a silicon substrate. Further, in order to decrease the surface recombination velocity, measures in a structure of the photoelectric conversion device, such as provision of a passivation film which terminates surface defects, are mainly taken. For example, Non-Patent Document 1 discloses a technique by which high conversion efficiency is obtained by employing a structure in which an area of a portion where a silicon substrate and an electrode are in contact with each other is reduced, and the silicon substrate is covered with a passivation film as much as possible.

### REFERENCE

### Non-Patent Document

[Non-Patent Document 1] A. W. Blakers, A. Wang, A. M. Milne, J. Zhao and M. A. Green, “22.8% Efficient Silicon Solar Cell”, Appl. Physics Letters, Vol. 55, pp. 1363-1365, 1989.

### SUMMARY OF THE INVENTION

However, the passivation film disclosed in Non-Patent Document 1 is a thermal oxidation film and an insulator. Accordingly, in order to connect the silicon substrate to the electrode, an opening needs to be provided in the passivation film, which increases the number of manufacturing steps.

Further, while the surface recombination velocity of the silicon substrate can be decreased by the passivation film, the area of the portion where the silicon substrate and the electrode are in contact with each other is reduced, which increases series resistance between a pair of electrodes of the photoelectric conversion device. The series resistance is one factor of degrading electrical characteristics of the photoelectric conversion device.

Therefore, an object of one embodiment of the present invention is to provide a photoelectric conversion device including a passivation film in which an opening for connection to an electrode does not need to be provided. Another object is to provide a photoelectric conversion device whose electrical characteristics are improved by inclusion of a passivation film.

One embodiment of the present invention disclosed in this specification relates to a photoelectric conversion device in which an oxide semiconductor layer containing an oxide of a metal belonging to any of Groups 4 to 8 in the periodic table as its main component is used as a passivation layer.

Another embodiment of the present invention disclosed in this specification is a photoelectric conversion device including, between a pair of electrodes, a silicon substrate having p-type conductivity; a silicon semiconductor layer having n-type conductivity which is provided over one surface of the silicon substrate and in contact with one of the pair of electrodes; and an oxide semiconductor layer having p-type conductivity which is provided over the other surface of the silicon substrate and in contact with the other of the pair of electrodes.

A thin film having a light-transmitting property (hereinafter, referred to as a light-transmitting thin film) may be formed over the silicon semiconductor layer. Formation of the light-transmitting thin film has an anti-reflection effect and/or a passivation effect. The light-transmitting thin film is not limited to a single layer, and may have a stacked-layer structure.

Further, part of a region of the silicon semiconductor layer may have a higher carrier concentration than the other part of the region of the silicon semiconductor layer, and the one of the pair of electrodes may be in contact with the region having a higher carrier concentration.

Furthermore, a silicon semiconductor layer having p-type conductivity may be formed between the silicon substrate and the oxide semiconductor layer.

Another embodiment of the present invention disclosed in this specification is a photoelectric conversion device including a silicon substrate having one conductivity type; an oxide semiconductor layer which is provided over one surface of the silicon substrate; a first impurity region which is provided over the other surface of the silicon substrate, has the same conductivity type as the silicon substrate, and has a higher carrier concentration than the silicon substrate; a second impurity region which has a conductivity type opposite to that of the silicon substrate; an insulating layer which is provided over the other surface of the silicon substrate; a first electrode which is in contact with the first impurity region; and a second electrode which is in contact with the second impurity region.

A light-transmitting thin film may be formed over the oxide semiconductor layer.

Further, the oxide semiconductor layer can be formed using a material whose band gap is greater than or equal to 2 eV. Further, the carrier concentration of the oxide semiconductor layer may be equal to or lower than the carrier concentration of the silicon substrate.

Furthermore, the oxide semiconductor layer is preferably formed using a material containing an oxide of a metal belonging to any of Groups 4 to 8 in the periodic table as its main component. For example, it is possible to use a material containing any of vanadium oxide, niobium oxide, tantalum oxide, chromium oxide, molybdenum oxide, tungsten oxide, manganese oxide, and rhenium oxide as its main component.

According to one embodiment of the present invention, a manufacturing step of forming an opening in a passivation film can be omitted. Further, a photoelectric conversion device having low series resistance between a pair of electrodes and favorable electrical characteristics can be provided.

### BRIEF DESCRIPTION OF THE DRAWINGS

In the accompanying drawings:

FIG. 1 is a cross-sectional view illustrating a photoelectric conversion device of one embodiment of the present invention;

FIG. 2 is a cross-sectional view illustrating a photoelectric conversion device of one embodiment of the present invention;

FIG. 3 is a cross-sectional view illustrating a photoelectric conversion device of one embodiment of the present invention;

FIG. 4 is a cross-sectional view illustrating a photoelectric conversion device of one embodiment of the present invention;

FIG. 5 is a cross-sectional view illustrating a photoelectric conversion device of one embodiment of the present invention;

FIGS. 6A to 6C are process cross-sectional views illustrating a method for manufacturing a photoelectric conversion device of one embodiment of the present invention;

FIGS. 7A to 7C are process cross-sectional views illustrating a method for manufacturing a photoelectric conversion device of one embodiment of the present invention;

FIGS. 8A and 8B each show I-V characteristics of an element in which a molybdenum oxide film is formed over a silicon substrate;

FIG. 9 is a cross-sectional view illustrating a photoelectric conversion device of one embodiment of the present invention; and

FIG. 10 is a cross-sectional view illustrating a photoelectric conversion device of one embodiment of the present invention.

### DETAILED DESCRIPTION OF THE INVENTION

Hereinafter, an embodiment of the present invention will be described in detail with reference to the accompanying drawings. However, the present invention is not limited to the description below, and it is easily understood by those skilled in the art that modes and details disclosed herein can be modified in various ways without departing from the spirit and the scope of the present invention. Therefore, the present invention is not construed as being limited to description of the embodiment. Note that in all drawings used to illustrate the embodiment, portions that are identical or portions having similar functions are denoted by the same reference numerals, and their repetitive description may be omitted.

In this embodiment, a photoelectric conversion device of one embodiment of the present invention and a method for manufacturing the photoelectric conversion device will be described.

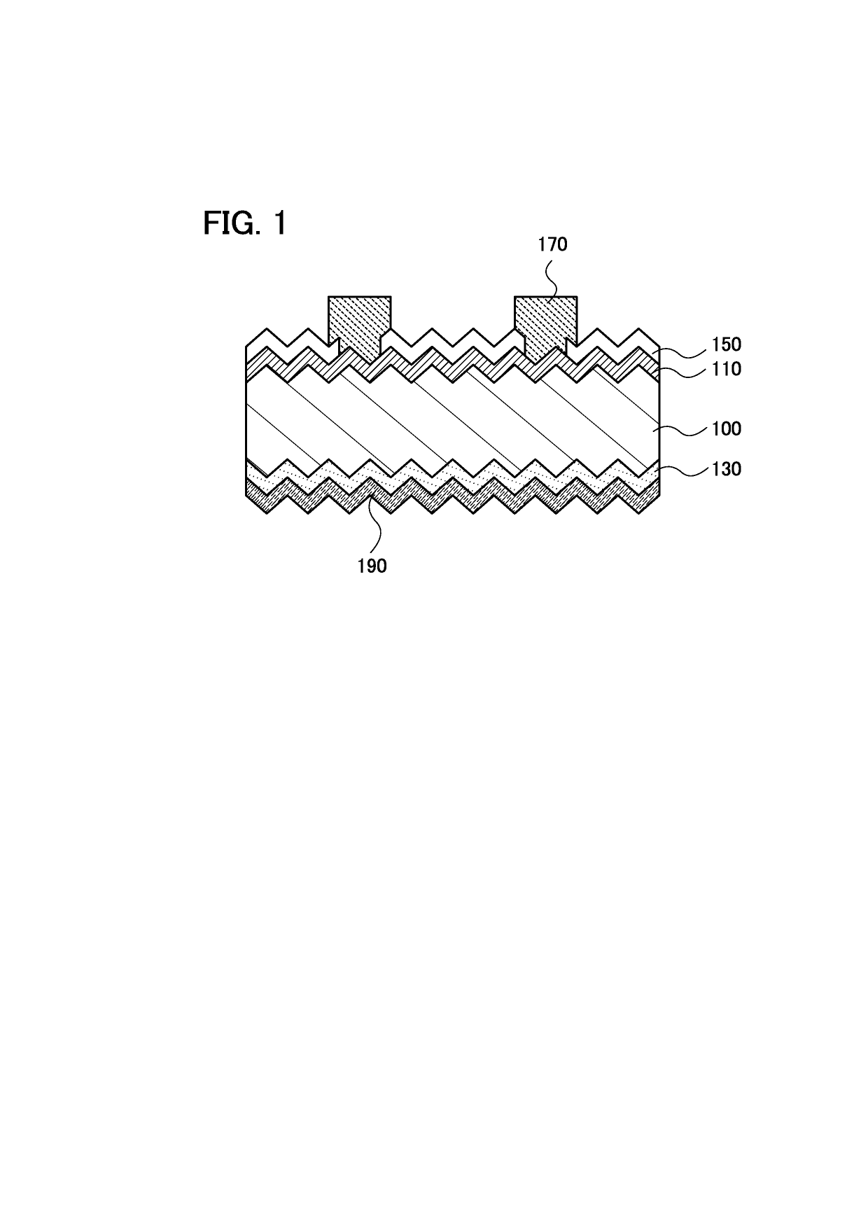

FIG. 1 is a cross-sectional view of a photoelectric conversion device of one embodiment of the present invention. The photoelectric conversion device includes a silicon substrate 100 having p-type conductivity; a silicon semiconductor layer 110 having n-type conductivity which is provided over one surface of the silicon substrate; an oxide semiconductor layer 130 having p-type conductivity which is provided over the other surface of the silicon substrate; a light-transmitting thin film 150 which is provided over the silicon semiconductor layer 110; a first electrode 170 which is in contact with the silicon semiconductor layer 110; and a second electrode 190 which is in contact with the oxide semiconductor layer 130. Note that the first electrode 170 is a grid electrode, and a surface on the first electrode 170 side serves as a light-receiving surface.

Further, FIG. 1 illustrates an example in which a front surface and a back surface of the silicon substrate 100 are processed to have unevenness. On the surface processed to have unevenness, incident light is reflected in a multiple manner, and the light obliquely propagates into a photoelectric conversion region; thus, the optical path length is increased. In addition, a light trapping effect in which reflected light by the back surface is totally reflected at the surface can occur.

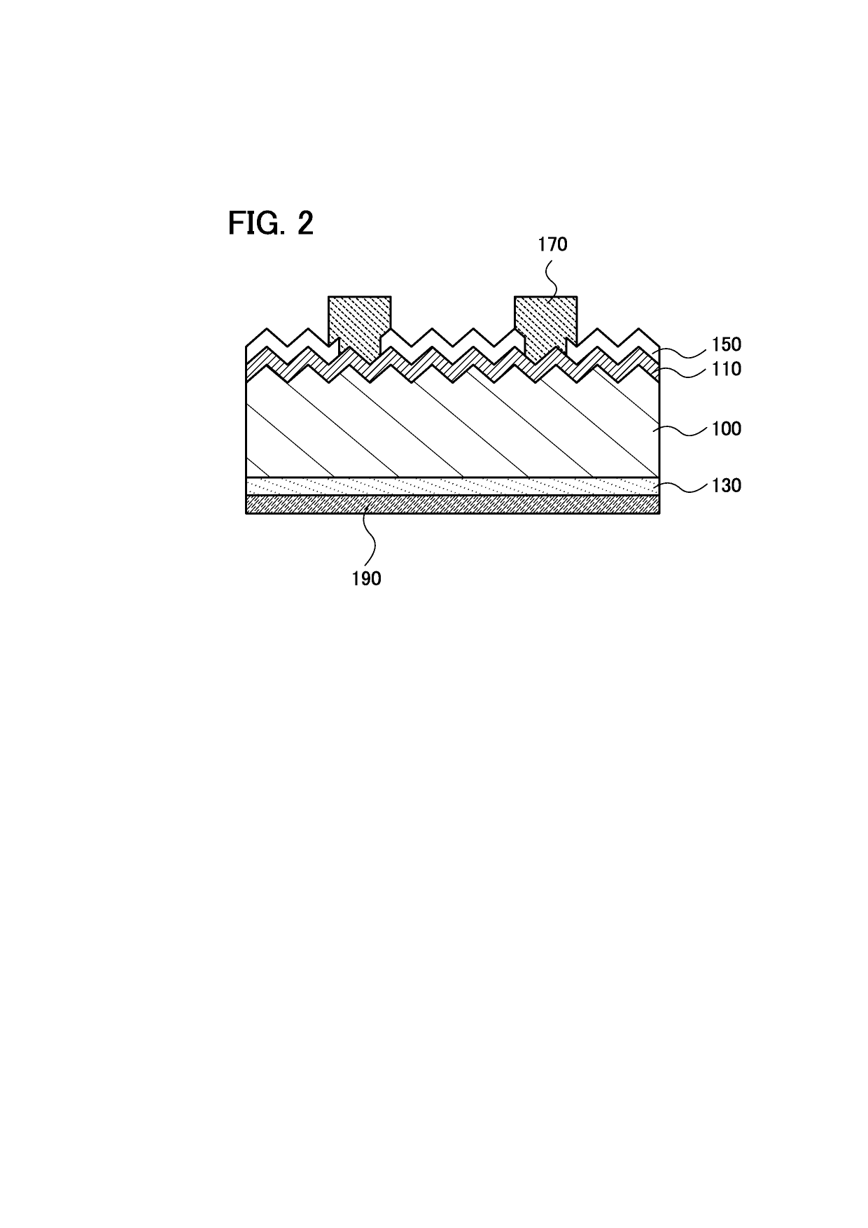

Note that as illustrated in FIG. 2, a structure in which only one of surfaces (the front surface and the back surface) of the silicon substrate 100 is processed to have unevenness may be employed. The surface area of the silicon substrate is increased by the unevenness; thus, while the optical effect described above can be obtained, the absolute amount of surface defects is increased. Therefore, in consideration of the balance between the optical effect and the amount of the surface defects, a practitioner may determine the structure so that more favorable electrical characteristics can be obtained.

The silicon substrate 100 has p-type conductivity, and the silicon semiconductor layer 110 has n-type conductivity. Accordingly, a p-n junction is formed between the silicon substrate 100 and the silicon semiconductor layer 110. Note that the silicon semiconductor layer 110 can be a surface layer of the silicon substrate 100 into which an impurity imparting n-type conductivity is diffused or a silicon film which is formed over the silicon substrate 100 and contains an impurity imparting n-type conductivity.

The oxide semiconductor layer 130 serves as a passivation layer which has an effect of terminating surface defects of the silicon substrate 100 and decreasing the surface recombination velocity. Further, the oxide semiconductor layer 130 of one embodiment of the present invention preferably has p-type conductivity. The oxide semiconductor layer 130 of one embodiment of the present invention may have n-type or i-type conductivity.

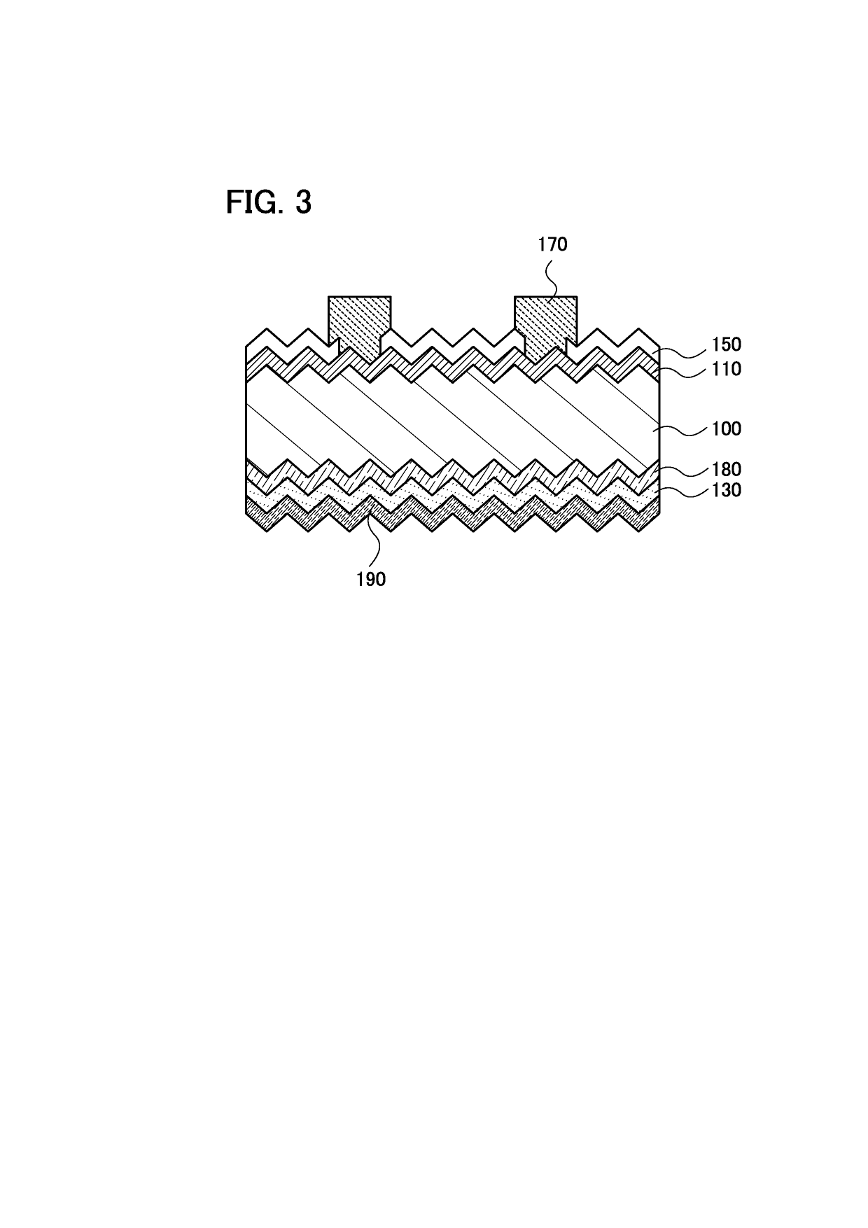

Further, as illustrated in FIG. 3, a silicon semiconductor layer 180 having p-type conductivity which has a higher carrier concentration than the silicon substrate 100 may be provided between the silicon substrate 100 and the oxide semiconductor layer 130. Note that the silicon semiconductor layer 180 can be formed using a region of the surface layer of the silicon substrate 100 into which an impurity imparting p-type conductivity is diffused or a silicon film which contains an impurity imparting p-type conductivity.

The silicon semiconductor layer 180 serves as a back surface field (BSF) layer. When the BSF layer is formed, a p-p⁺ junction is formed, and minority carriers are repelled by the electric field of the p-p⁺ junction and attracted to the p-n junction side, whereby recombination of carriers in the vicinity of the second electrode 190 can be prevented. Further, in a structure where the silicon semiconductor layer 180 is not formed, the oxide semiconductor layer 130 having p-type conductivity can serve as a BSF layer.

Note that in this specification, in the case where materials which have the same conductivity type and have different carrier concentrations need to be distinguished, the conductivity type of a material having a relatively higher carrier concentration is referred to as n⁺-type or p⁺-type, whereas the conductivity type of a material having a relatively lower carrier concentration is referred to as n⁻-type or p⁻-type.

The light-transmitting thin film 150 formed over the silicon semiconductor layer 110 serves as an anti-reflection film. The light-transmitting thin film 150 can be a light-transmitting dielectric film, a light-transmitting conductive film, or the like. Provision of the anti-reflection film enables light loss due to reflection on the light-receiving surface to be reduced. Note that the light-transmitting thin film 150 may be provided as necessary.

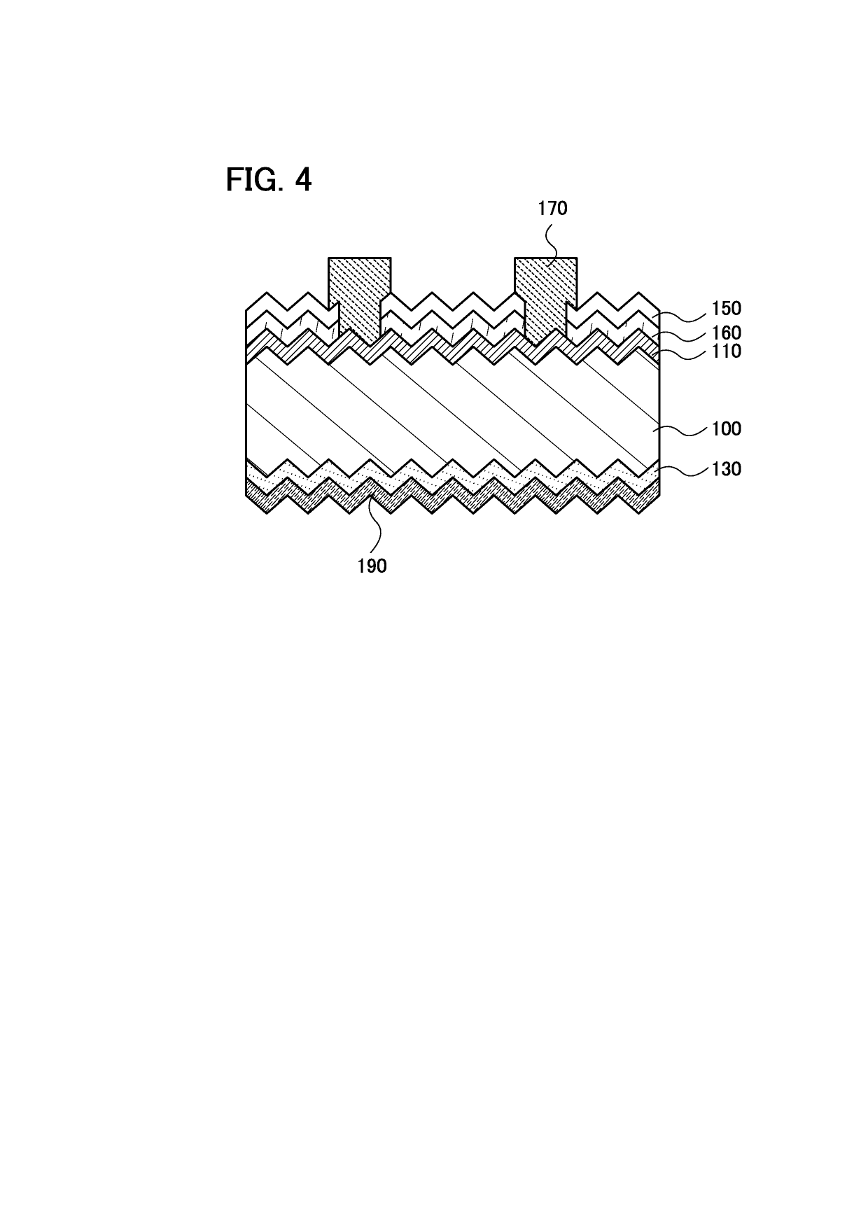

Furthermore, as illustrated in FIG. 4, a passivation layer 160 may be provided between the silicon semiconductor layer 110 and the light-transmitting thin film 150. The passivation layer 160 can be formed using an insulating film such as an oxide film of silicon or a nitride film of silicon. Provision of the passivation layer 160 enables surface defects of the silicon semiconductor layer 110 to be reduced, so that electrical characteristics of the photoelectric conversion device can be improved. Note that the passivation layer 160 may be used as an anti-reflection film without providing the light-transmitting thin film 150.

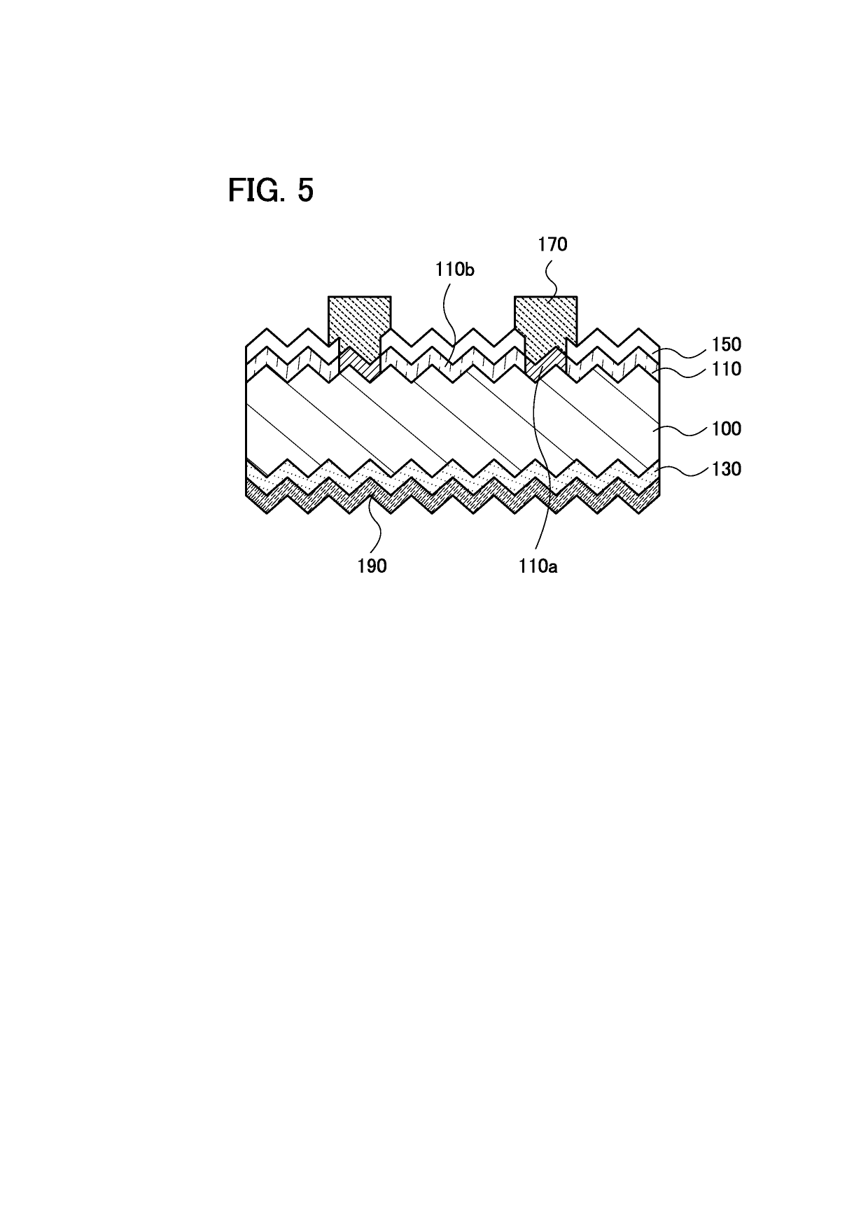

In addition, as illustrated in FIG. 5, the following structure may be employed: part of the silicon semiconductor layer 110 is an n⁺-type region 110a and the other part of the silicon semiconductor layer 110 is an n⁻-type region 110b, and the n⁺-type region 110a is in contact with the first electrode 170. By employing such a structure, the absolute amount of defects in the entire silicon semiconductor layer 110 and surface defects thereof can be reduced, so that electrical characteristics of the photoelectric conversion device can be improved.

Note that the photoelectric conversion device may have a structure in which structures of FIG. 1, FIG. 2, FIG. 3, FIG. 4, and FIG. 5 are combined as appropriate.

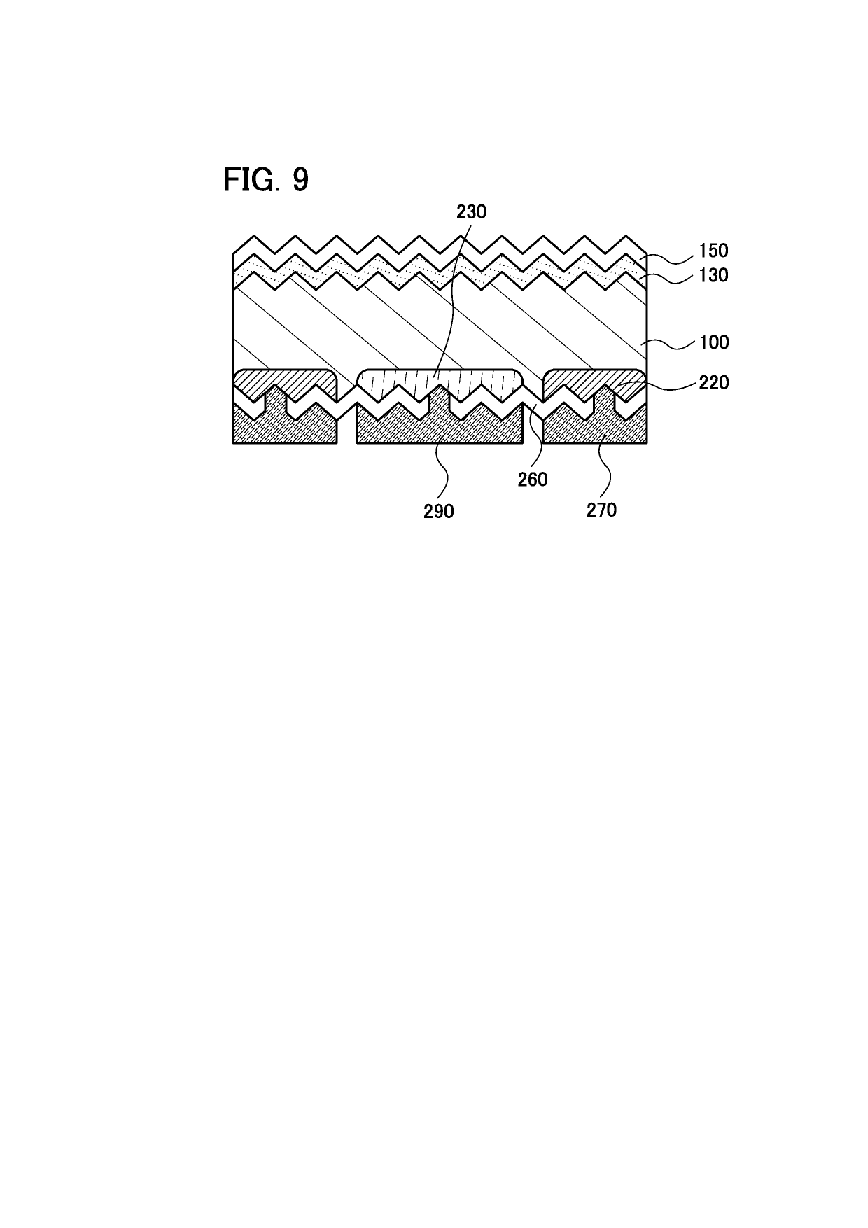

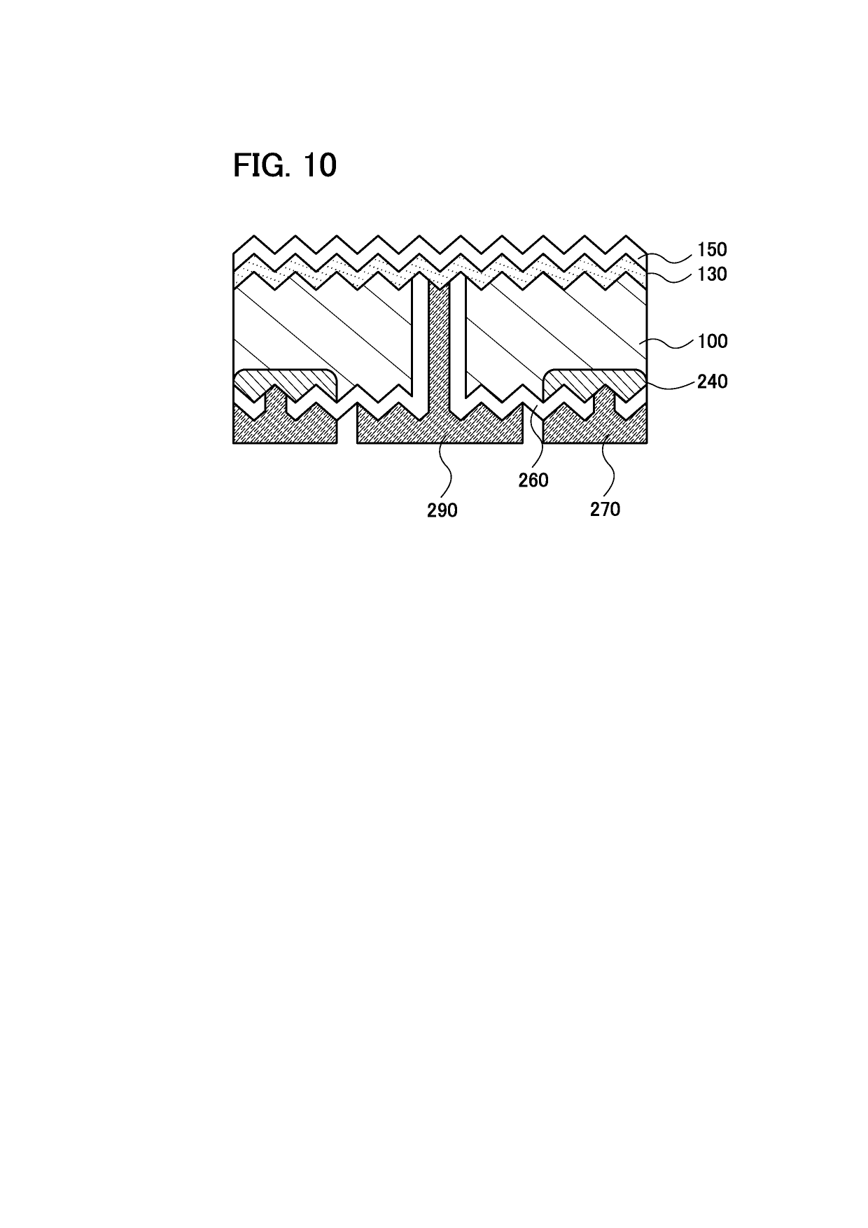

Further, the photoelectric conversion device of one embodiment of the present invention may have a structure illustrated in FIG. 9 or FIG. 10. A photoelectric conversion device illustrated in FIG. 9 includes the silicon substrate 100 having one conductivity type; the oxide semiconductor layer 130 which is provided over the surface of the silicon substrate; a first impurity region 220 which is provided over the back surface of the silicon substrate, has the same conductivity type as the silicon substrate 100, and has higher carrier concentration than the silicon substrate; a second impurity region 230 having a conductivity type opposite to that of the silicon substrate; an insulating layer 260; the light-transmitting thin film 150 which is provided over the oxide semiconductor layer 130; a first electrode 270 which is in contact with the first impurity region 220; and a second electrode 290 which is in contact with the second impurity region 230. In other words, the photoelectric conversion device has a back contact structure in which the electrodes and the impurity regions are provided only over the back surface of the silicon substrate. Note that the silicon substrate 100 may have either p-type conductivity or n-type conductivity. Further, the light-transmitting thin film 150 serves as an anti-reflection film and may be provided as necessary.

The oxide semiconductor layer 130 provided over the surface of the silicon substrate 100 has a function of suppressing recombination of carriers by band bending in the vicinity where the oxide semiconductor layer 130 and the silicon substrate are in contact with each other or the potential barrier of the oxide semiconductor layer 130. Further, a silicon oxide film may be formed by a reaction caused at an interface between the oxide semiconductor layer 130 and the silicon substrate 100. The silicon oxide film is interposed at the interface between the oxide semiconductor layer 130 and the silicon substrate 100, whereby a higher potential barrier is formed, so that a higher passivation effect can be obtained. Accordingly, the oxide semiconductor layer 130 can be used as a passivation film on the surface side of the photoelectric conversion device having a back contact structure.

A photoelectric conversion device illustrated in FIG. 10 includes the silicon substrate 100 having one conductivity type; the oxide semiconductor layer 130 which is provided over the surface of the silicon substrate and has a conductivity type opposite to that of the silicon substrate; an impurity region 240 which has the same conductivity type as the silicon substrate 100, has a higher carrier concentration than the silicon substrate, and is formed over the back surface of the silicon substrate; the insulating layer 260 which is provided over the back surface of the silicon substrate and on a wall surface of an opening penetrating the silicon substrate; the light-transmitting thin film 150 which is provided over the oxide semiconductor layer 130; the first electrode 270 which is in contact with the oxide semiconductor layer 130 through the opening penetrating the silicon substrate 100; and the second electrode 290 which is in contact with the impurity region 240.

In the structure illustrated in FIG. 10, the oxide semiconductor layer 130 has a function of suppressing recombination of carriers on the surface of the silicon substrate 100 as in the structure illustrated in FIG. 9, and also has a function of a layer for forming a p-n junction with the silicon substrate 100.

For the oxide semiconductor layer 130 of one embodiment of the present invention, it is possible to use an inorganic compound containing, as its main component, a transition metal oxide having a band gap greater than or equal to 2 eV, preferably greater than or equal to 2.5 eV. It is particularly preferable that the inorganic compound be an oxide of a metal belonging to any of Groups 4 to 8 in the periodic table. Further, the carrier concentration of the oxide semiconductor layer 130 may be equal to or lower than the carrier concentration of the silicon substrate 100. For example, the carrier concentration of the oxide semiconductor layer 130 may be equal to or lower than a half of the carrier concentration of the silicon substrate 100.

Specifically, as the metal oxide, vanadium oxide, niobium oxide, tantalum oxide, chromium oxide, molybdenum oxide, tungsten oxide, manganese oxide, rhenium oxide, or the like can be used. Among these, molybdenum oxide is especially preferable since it is stable in the air, has a low hygroscopic property, and is easily handled.

Further, an impurity is added to the metal oxide, whereby the conductivity type can be changed. Furthermore, even in the case where an impurity is not intentionally added to the metal oxide, a defect in the metal oxide, and a slight amount of an impurity introduced into the metal oxide during film formation cause the formation of a donor level or an acceptor level in some cases, so that the metal oxide exhibits n-type or p-type conductivity in some cases.

The conductivity type can be also changed by mixing, as an accessory component, a material having a different chemical composition into a material containing the above-described metal oxide as its main component or existence of oxygen vacancies.

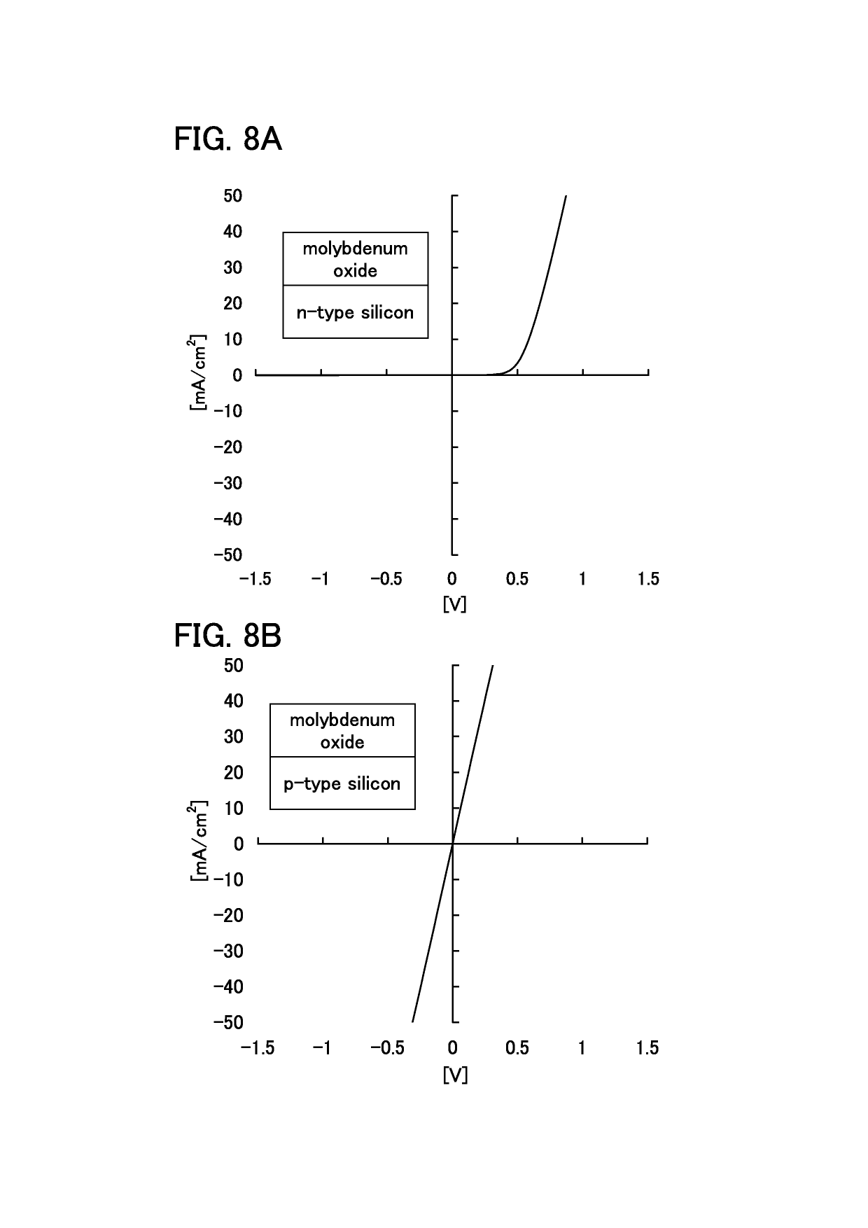

For example, when molybdenum trioxide powder (4N MOO03PB) manufactured by Kojundo Chemical Laboratory Co., Ltd. is put in a tungsten boat (BB-3) manufactured by Furuuchi Chemical Corporation, and resistance-heating evaporation is performed on silicon substrates at a deposition rate of 0.2 nm/sec in vacuum of less than or equal to 1×10⁻⁴ Pa, elements having different I-V characteristics because of difference in the conductivity type between the silicon substrates are formed. FIG. 8A shows I-V characteristics of an element in which a molybdenum oxide film is formed over an n-type silicon substrate by the above method, and FIG. 8B shows I-V characteristics of an element in which a molybdenum oxide film is formed over a p-type silicon substrate by the above method. FIG. 8A shows a rectifying property, and FIG. 8B shows an ohmic property. Accordingly, it can be said that a p-n junction is formed in the element exhibiting the property in FIG. 8A. Thus, the molybdenum oxide films formed by the above method exhibit a rectifying property only in a heterojunction using the n-type silicon substrate, and thus it is found that the molybdenum oxide films have p-type conductivity with a high carrier concentration.

Note that the electric conductivity, the refractive index, the extinction coefficient, and the optical band gap obtained from a Tauc plot of each of the molybdenum oxide films formed by the above evaporation are 1×10⁻⁶ S/cm to 3.8×10⁻³ S/cm (dark conductivity), 1.6 to 2.2 (a wavelength: 550 nm), 6×10⁻⁴ to 3×10⁻³ (a wavelength of 550 nm), and 2.8 eV to 3 eV, respectively.

Further, the metal oxide has a high passivation effect and can reduce defects on a surface of silicon, which can improve the lifetime of carriers.

For example, molybdenum oxide films are formed on both surfaces of an n-type single crystal silicon substrate having a resistivity of approximately 9 Ω·cm and serve as passivation films. According to the measurement by a microwave photoconductivity decay (μ-PCD) method, the effective lifetime at this time is about 400 msec. Further, the lifetime of the n-type single crystal silicon substrate, on which chemical passivation using an alcoholic iodine solution has been performed, which is the bulk lifetime of the single crystal silicon substrate, is also about 400 μsec. Note that the effective lifetime of the n-type single crystal silicon substrate where a passivation film is not formed is about 40 μsec.

Since the oxide semiconductor layer 130 of one embodiment of the present invention has conductivity, the second electrode 190 and the silicon substrate 100 can be connected to each other through the oxide semiconductor layer 130. Accordingly, the surface defects on almost the entire surface of the other surface of the silicon substrate can be reduced. Further, it is not necessary to form an opening for connection to the electrode in the oxide semiconductor layer 130, so that the number of manufacturing steps can be reduced.

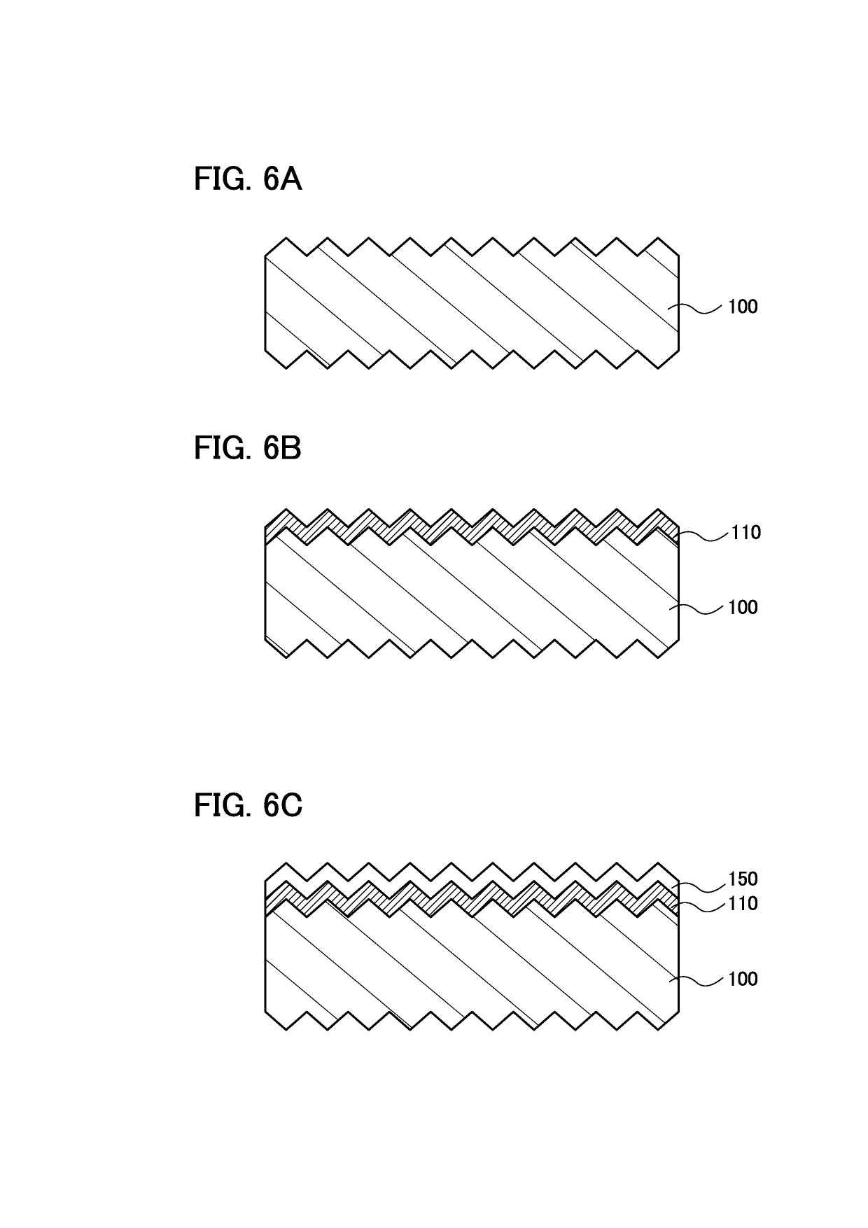

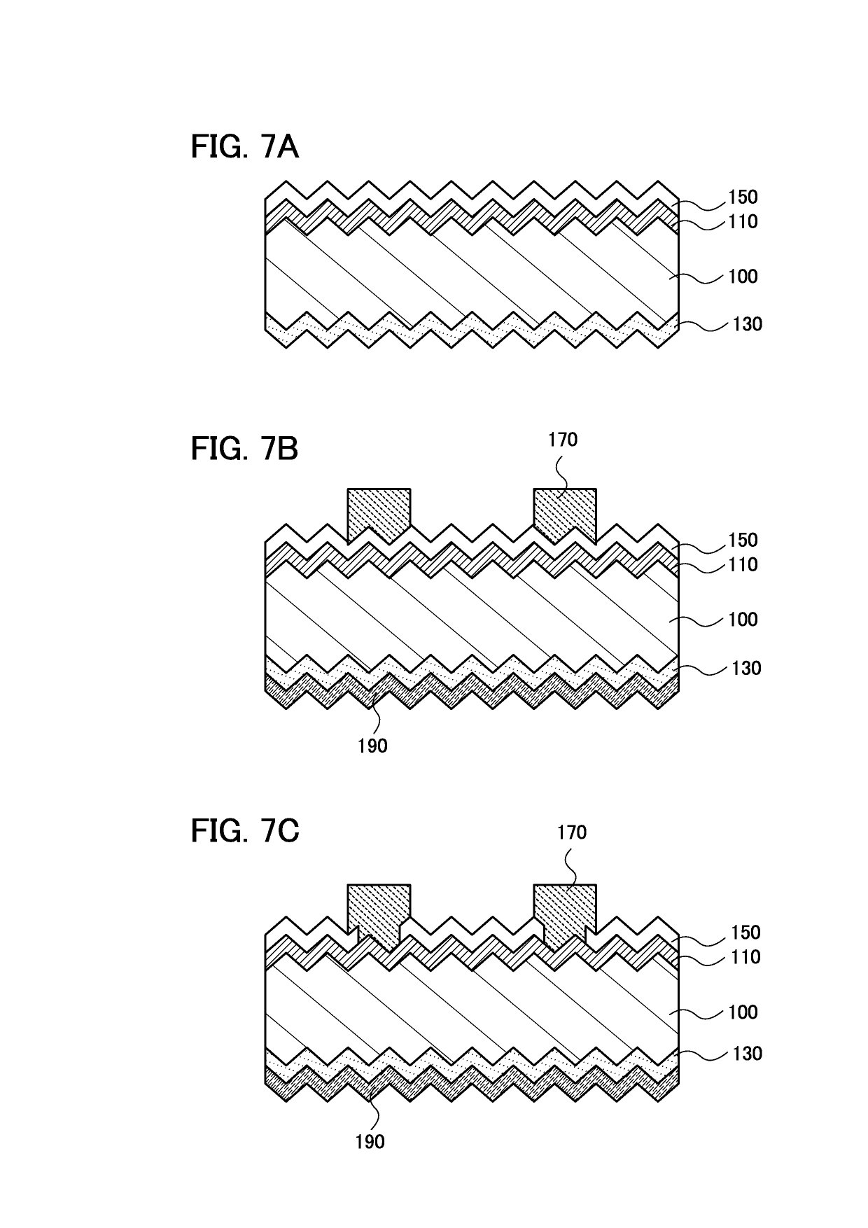

Next, a method for manufacturing the photoelectric conversion device, which is illustrated in FIG. 1, will be described with reference to FIGS. 6A to 6C and FIGS. 7A to 7C.

In one embodiment of the present invention, a single crystal silicon substrate or a polycrystalline silicon substrate can be used as the silicon substrate 100. The manufacturing method and the conductivity type of the silicon substrate are not specifically limited. In this embodiment, described is an example in which a p-type single crystal silicon substrate whose surface corresponds to the (100) plane and which is manufactured by a Magnetic Czochralski (MCZ) method is used.

Next, the front surface and the back surface of the silicon substrate 100 are processed to have unevenness (see FIG. 6A). Note that here, an example in which the above-described single crystal silicon substrate having a (100) plane as a surface is used is employed to describe a method for processing the silicon substrate 100 to have unevenness. In the case where a polycrystalline silicon substrate is used as the silicon substrate 100, unevenness may be formed by a dry etching method, a wet etching using a metal catalyst such as silver, or the like.

In the case where the initial single crystal silicon substrate is a substrate which is subjected to only a slicing process, a damage layer with a thickness of 10 μm to 20 μm, remaining on the surface of the single crystal silicon substrate, is removed by a wet etching process. For an etchant, an alkaline solution with a relatively high concentration, for example, 10% to 50% sodium hydroxide solution, or 10% to 50% potassium hydroxide solution can be used. Alternatively, a mixed acid in which hydrofluoric acid and nitric acid are mixed, or the mixed acid to which acetic acid is further added may be used.

Next, impurities adhering to the surfaces of the single crystal silicon substrate from which the damage layers have been removed are removed by acid cleaning. As an acid, for example, a mixture (FPM) of 0.5% hydrofluoric acid and 1% hydrogen peroxide, or the like can be used. Alternatively, RCA cleaning or the like may be performed. Note that this acid cleaning may be omitted.

The unevenness is formed utilizing a difference in etching rates among plane orientations in etching of the crystalline silicon using the alkaline solution. For an etchant, an alkaline solution with a relatively low concentration, for example, 1% to 5% sodium hydroxide solution, or 1% to 5% potassium hydroxide solution can be used, preferably several percent isopropyl alcohol is added thereto. The temperature of the etchant is 70° C. to 90° C., and the single crystal silicon substrate is soaked in the etchant for 30 to 60 minutes. By this treatment, unevenness including a plurality of minute projections each having a substantially square pyramidal shape and recessions formed between adjacent projections can be formed on the surfaces of the single crystal silicon substrate.

Next, oxide layers which are non-uniformly formed on the silicon surface in the etching step for forming the unevenness are removed. Another purpose to remove the oxide layer is to remove a component of the alkaline solution, which is likely to remain in the oxide layer. When an alkali metal ion, e.g., an Na ion or a K ion enters silicon, the lifetime is decreased, and the electrical characteristics of the photoelectric conversion device are drastically lowered as a result. Note that in order to remove the oxide layer, 1 to 5 percent diluted hydrofluoric acid may be used.

Next, the following step may be performed: the surfaces of the single crystal silicon substrate are etched with a mixed acid in which hydrofluoric acid and nitric acid are mixed, or the mixed acid to which acetic acid is further added so that impurities such as a metal component are removed from the surfaces. By adding the acetic acid, oxidizing ability of nitric acid can be kept so as to stably perform the etching, and the etching rate can be made constant. For example, a volume ratio of hydrofluoric acid (approximately 50%), nitride acid (60% or more) and acetic acid (90% or more) can be 1:1.5 to 3:2 to 4. Note that in this specification, the mixed acid solution containing hydrofluoric acid, nitric acid, and acetic acid is referred to as HF-nitric-acetic acid. Further, in the etching with the HF-nitric-acetic acid, angles in cross sections of vertexes of the projections are made larger, so that a surface area can be reduced, and the absolute amount of surface defects can be reduced. Note that in the case where the etching with the HF-nitric-acetic acid is performed, the above step of removing the oxide layers with diluted hydrofluoric acid can be omitted. Through the steps up to here, the surfaces of the single crystal silicon substrate that is the silicon substrate 100 can have unevenness.

Next, after appropriate cleaning, the silicon semiconductor layer 110 having n-type conductivity is formed over the one surface of the silicon substrate 100, which serves as a light-receiving surface (see FIG. 6B). In this embodiment, an example where the surface layer of the silicon substrate 100 (a diffusion layer) into which an impurity imparting n-type conductivity is diffused is formed as the silicon semiconductor layer will be described.

As an impurity imparting n-type conductivity, phosphorus, arsenic, antimony, or the like can be given. For example, the silicon substrate 100 is subjected to heat treatment at a temperature higher than or equal to 800° C. and lower than or equal to 900° C. in an atmosphere of phosphorus oxychloride, whereby phosphorus can be diffused at a depth of approximately 0.5 μm from the surface of the silicon substrate 100.

In order that the diffusion layer is not formed on the other surface side of the silicon substrate 100 which is a side opposite to the light-receiving surface, a surface which is on a side opposite to the surface over which the diffusion layer is to formed may be covered with a mask such as an inorganic insulating film, which is formed using a heat resistant material, and after the diffusion layer is formed, the mask may be removed.

Next, the light-transmitting thin film 150 is formed over the silicon semiconductor layer 110 as an anti-reflection film (see FIG. 6C). The light-transmitting thin film 150 may be formed with a single layer or a stacked layer of a light-transmitting conductive film(s) or a light-transmitting dielectric film(s) containing any of indium tin oxide; indium tin oxide containing silicon; indium oxide containing zinc; zinc oxide; zinc oxide containing gallium; zinc oxide containing aluminum; tin oxide; tin oxide containing fluorine; tin oxide containing antimony; graphene; niobium oxide; titanium oxide; magnesium fluoride; zinc sulfide; and the like. The light-transmitting conductive film or the light-transmitting dielectric film can be formed by a sputtering method or an evaporation method. Alternatively, a silicon oxide film or a silicon nitride film may be used as the light-transmitting thin film 150. Such a film can be formed by a plasma CVD method or the like.

Subsequently, the oxide semiconductor layer 130 is formed on the other surface side of the silicon substrate 100 which is a side opposite to the light-receiving surface (see FIG. 7A). For the oxide semiconductor layer, the above-described metal oxide can be used. Here, an example in which a p-type molybdenum oxide film is formed will be described.

The p-type molybdenum oxide film can be formed by a vapor phase method such as an evaporation method, a sputtering method, or an ion plating method. As an evaporation method, a method in which a material of molybdenum oxide alone is evaporated, or a method in which a material of molybdenum oxide and an impurity imparting p-type conductivity are co-evaporated may be used. Note that the co-evaporation refers to an evaporation method in which evaporation is carried out from a plurality of evaporation sources at the same time in one treatment chamber. As a sputtering method, a method in which molybdenum oxide, molybdenum, or any of the above materials which contains an impurity imparting p-type conductivity is used as a target, and oxygen or a mixed gas of oxygen and a rare gas such as argon is used as a sputtering gas may be used. As an ion plating method, a method in which a film is formed in plasma containing oxygen using a material similar to the material used in the sputtering method described above may be used.

In this embodiment, a method in which a material of molybdenum oxide alone is evaporated is used. As an evaporation source, powder of molybdenum trioxide can be used. The purity of the powder of molybdenum trioxide is preferably 99.99% (4N) to 99.9999% (6N). The evaporation is preferably performed in a high vacuum of 5×10⁻³ Pa or less, preferably 1×10⁻⁴ Pa or less.

Next, the second electrode 190 is formed over the oxide semiconductor layer 130. The second electrode 190 can be formed using a low-resistance metal such as silver, aluminum, or copper by a sputtering method, a vacuum evaporation method, or the like. Alternatively, the second electrode 190 may be formed in such a manner that a conductive resin such as a silver paste, a copper paste, or an aluminum paste is applied by a screen printing method and baked.

Then, a conductive resin to be the first electrode 170 is applied on the light-transmitting thin film 150 (see FIG. 7B). The first electrode 170 is a grid electrode and is preferably formed in such a manner that a conductive resin such as a silver paste, a copper paste, a nickel paste, or a molybdenum paste is applied by a screen printing method. Further, the first electrode 170 may be a stacked layer of different materials, such as a stacked layer of a silver paste and a copper paste. Further, the conductive resin may be applied by a dispensing method or an ink-jet method.

After that, the conductive resin to be the first electrode 170 is baked, whereby the silicon semiconductor layer 110 and the first electrode 170 are in contact with each other (see FIG. 7C). The conductive resin and the silicon semiconductor layer 110 are not in contact with each other at the aforementioned stage where the conductive resin is applied because the light-transmitting thin film 150 is provided therebetween. However, by baking the conductive resin, the conductor component of the conductive resin penetrates the light-transmitting thin film 150, so that the conductive resin can be in contact with the silicon semiconductor layer 110. Note that in the case where the light-transmitting thin film 150 has conductivity, the silicon semiconductor layer 110 does not need to be in direct contact with the first electrode 170.

Note that in order to form the photoelectric conversion device having the structure illustrated in FIG. 2, before a process for forming unevenness, a resist mask formed using an inorganic material or the like may be provided on a surface where the unevenness is not formed.

In order to form the photoelectric conversion device having the structure illustrated in FIG. 3, before the oxide semiconductor layer 130 is formed, an impurity imparting p-type conductivity (e.g. boron, aluminum, or gallium) may be diffused to the other surface of the silicon substrate 100 which is a side opposite to the light-receiving surface.

In order to form the photoelectric conversion device having the structure illustrated in FIG. 4, the passivation layer 160 may be formed before the light-transmitting thin film 150 is formed.

In order to form the photoelectric conversion device having the structure illustrated in FIG. 5, first, the entire silicon semiconductor layer 110 is formed to have n⁻-type conductivity through a step of diffusing an impurity, and the light-transmitting thin film 150 having an opening is formed, and then the n⁺-type region 110a is formed in part of the silicon semiconductor layer through another step of diffusing an impurity. After that, the first electrode 170 may be formed so as to be in contact with the n⁺-type region 110a.

In the above manner, the photoelectric conversion device in which an oxide semiconductor layer is used as a passivation layer, which is one embodiment of the present invention, can be manufactured.

This application is based on Japanese Patent Application serial no. 2012-007650 filed with Japan Patent Office on Jan. 18, 2012, and Japanese Patent Application serial no. 2012-107483 filed with Japan Patent Office on May 9, 2012, the entire contents of which are hereby incorporated by reference.

What is claimed is:

1. A photoelectric conversion device comprising:
a first electrode;
a first semiconductor layer over and in contact with the first electrode;
a second semiconductor layer over the first semiconductor layer;
a third semiconductor layer over the second semiconductor layer; and
a second electrode over the third semiconductor layer,
wherein the first semiconductor layer contains a metal oxide semiconductor,
wherein the second semiconductor layer has a first conductivity type,
wherein the third semiconductor layer has a second conductivity type that is opposite to the first conductivity type, and
wherein a carrier concentration of the first semiconductor layer is lower than a carrier concentration of the second semiconductor layer.

2. The photoelectric conversion device according to claim 1, further comprising a light-transmitting thin film over the third semiconductor layer.

3. The photoelectric conversion device according to claim 1,
wherein the third semiconductor layer includes a first region in contact with the second electrode, and
wherein a carrier concentration of the first region is higher than a carrier concentration of a second region of the third semiconductor layer.

4. The photoelectric conversion device according to claim 1, wherein a band gap of the metal oxide semiconductor is greater than or equal to 2 eV.

5. The photoelectric conversion device according to claim 1, wherein the metal oxide semiconductor contains a metal belonging to any of Groups 4 to 8 in the periodic table as its main component.

6. The photoelectric conversion device according to claim 1, wherein the metal oxide semiconductor contains a material containing any of vanadium oxide, niobium oxide, tantalum oxide, chromium oxide, molybdenum oxide, tungsten oxide, manganese oxide, and rhenium oxide as its main component.

7. The photoelectric conversion device according to claim 1, wherein the first electrode is electrically connected to the second semiconductor layer via the first semiconductor layer.

8. The photoelectric conversion device according to claim 1, wherein the second electrode is positioned on a light-receiving side of the photoelectric conversion device.

9. A photoelectric conversion device comprising:
a first electrode;
an oxide semiconductor layer over and in contact with the first electrode;
a first semiconductor layer over the oxide semiconductor layer;
a second semiconductor layer over the first semiconductor layer;
a third semiconductor layer over the second semiconductor layer; and
a second electrode over the third semiconductor layer,
wherein the first semiconductor layer contains a metal oxide semiconductor,
wherein the second semiconductor layer contains silicon,
wherein the third semiconductor layer contains silicon,
wherein the first semiconductor layer has p-type conductivity,
wherein the second semiconductor layer has p-type conductivity, and
wherein the third semiconductor layer has n-type conductivity.

10. The photoelectric conversion device according to claim 9, further comprising a light-transmitting thin film over the third semiconductor layer.

11. The photoelectric conversion device according to claim 9,
wherein the third semiconductor layer includes a first region in contact with the second electrode, and
wherein a carrier concentration of the first region is higher than a carrier concentration of a second region of the third semiconductor layer.

12. The photoelectric conversion device according to claim 9, further comprising a fourth semiconductor layer between the first semiconductor layer and the second semiconductor layer,
wherein the fourth semiconductor layer contains silicon,
wherein the fourth semiconductor layer has p-type conductivity, and
wherein a carrier concentration of the fourth semiconductor layer is higher than a carrier concentration of the second semiconductor layer.

13. The photoelectric conversion device according to claim 9, wherein a band gap of the metal oxide semiconductor is greater than or equal to 2 eV.

14. The photoelectric conversion device according to claim 9, wherein the metal oxide semiconductor contains a metal belonging to any of Groups 4 to 8 in the periodic table as its main component.

15. The photoelectric conversion device according to claim 9, wherein the metal oxide semiconductor contains a material containing any of vanadium oxide, niobium oxide, tantalum oxide, chromium oxide, molybdenum oxide, tungsten oxide, manganese oxide, and rhenium oxide as its main component.

16. A photoelectric conversion device comprising:
a first electrode;
a second electrode;
a first impurity region over and in contact with the first electrode;
a second impurity region over and in contact with the second electrode;
a first semiconductor layer over the first impurity region and the second impurity region; and
a second semiconductor layer over and in contact with the first semiconductor layer,
wherein the second semiconductor layer comprises a metal oxide semiconductor,
wherein the first impurity region has a first conductivity type,
wherein the first semiconductor layer has the first conductivity type,
wherein the second impurity region has a second conductivity type that is opposite to the first conductivity type, and
wherein a carrier concentration of the first impurity region is higher than a carrier concentration of the first semiconductor layer.

17. The photoelectric conversion device according to claim 16, wherein a band gap of the metal oxide semiconductor is greater than or equal to 2 eV.

18. The photoelectric conversion device according to claim 16, wherein the metal oxide semiconductor contains a metal belonging to any of Groups 4 to 8 in the periodic table as its main component.

19. The photoelectric conversion device according to claim 16, wherein the metal oxide semiconductor contains a material containing any of vanadium oxide, niobium oxide, tantalum oxide, chromium oxide, molybdenum oxide, tungsten oxide, manganese oxide, and rhenium oxide as its main component.
